(19) United States
(12) Patent Application Publication
(10) Pub. No.: US 2010/0025699 A1
(43) Pub. Date: Feb. 4, 2010

(54) LIGHT EMITTING DIODE CHIP PACKAGE

(75) Inventors: Chia-Chi Liu, Taipei County (TW); Chih-Chieh Hu, Taipei County (TW); Yu-Tsung Tsai, Taipei County (TW); Pao-Chi Chi, Taipei County (TW); Chi-Ju Shen, Taipei County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: LUSTROUS INTERNATIONAL TECHNOLOGY LTD., Taipei County (TW)

(21) Appl. No.: 12/182,151

(22) Filed: Jul. 30, 2008

(51) Int. Cl. H01L 33/00

(52) U.S. Cl. 257/89; 257/E33.061

(57) ABSTRACT

A light emitting diode (LED) chip package is provided. The LED chip package comprises a carrier, a first LED chip, a second LED chip and an encapsulant. The first LED chip is disposed on and electrically connected to the carrier, wherein the first LED chip is adapted for emitting a first light. The second LED chip is disposed on and electrically connected to the carrier, wherein the second LED chip is adapted for emitting a second light. The encapsulant has a doped phosphor, and encapsulates the first LED chip and the second LED chip, wherein the first light is adapted for exciting the doped phosphor to emit a third light.

### BACKGROUND OF THE INVENTION

1. Field of the Invention

The present invention generally relates to an LED chip package, in particular, to an LED chip package emits a white light.

2. Description of Related Art

Since the light-emitting diode (LED) chip package has such advantages as long service life, small volume, high shock resistance, low heat output, and low power consumption, it has been widely utilized in indicators or light sources for household appliances and various instruments. In recent years, the LED chip package has been developed towards multicolor and high brightness; therefore, its application scope has been expanded to large outdoor display boards, traffic signal lights, and the like. In the future, it may even become the main illumination light source with both power-saving and environment-protecting functions.

With the development of the information industry and the semiconductor technology, flat displays has replaced the conventional cathode ray tube (CRT) display and becomes the main stream in the display market wherein a liquid crystal display (LCD) is the most popular product. The display media of the LCD is liquid crystal which can not emit light itself. Therefore, the LCD needs an exterior light source to display. Among the light sources using in the LCD, the LED chip packages are the common one because the advantages above-described.

As a full colour LCD displays an image, a white light which is the mixture of visible lights with various wavelengths is preferred provided to the LCD for performing a high display quality. Three LED chip packages emitting respectively red light, green light, and blue light are usually coordinated as a set and disposed in the full colour LCD to obtain the white light. Nevertheless, the cost and the product volume would be increased along with the increasing of the amount of LED chip packages using in the display.

Therefore, a white light LED chip package is provided. The white light LED chip package is composed of an LED chip which emits a blue light and a doped phosphor which is adapted for exciting by the blue light to emit a yellow light. The mixture of the blue light and the yellow light is rather similar to the white light. Thus, the amount of white light LED chip packages using in the display is decreased obviously.

However, the wave length of the light which human beings can observe are about 400 nm to 700 nm wherein the wavelength of the blue light is about 435 nm to 480 nm and the wavelength of the yellow light is about 580 nm to 595 nm. Therefore, the white light emitted by the white light LED chip packages composed of blue LED chip and yellow doped phosphor may be lack of the light having longer wavelength, for example the red light. Accordingly, the LCD uses the white light LED chip packages composed of blue LED chip and yellow doped phosphor as the displaying light source may not be truly display red images.

### SUMMARY OF THE INVENTION

Accordingly, the present invention is directed to an LED chip package which emits a white light with various wavelengths.

The present invention provides a light emitting diode (LED) chip package. The LED chip package comprises a carrier, a first LED chip, a second LED chip and an encapsulant. The first LED chip is disposed on and electrically connected to the carrier, wherein the first LED chip is adapted for emitting a first light. The second LED chip is disposed on and electrically connected to the carrier, wherein the second LED chip is adapted for emitting a second light. The encapsulant has a doped phosphor, and encapsulates the first LED chip and the second LED chip, wherein the first light is adapted for exciting the doped phosphor to emit a third light.

According to an embodiment of the present invention, the carrier comprises a substrate and an integrated circuit. the integrated circuit is disposed on the carrier and electrically connected to the substrate, wherein the integrated circuit comprises a plurality of complementary metal-oxide-semiconductor (CMOS) devices and the first LED ship and the second LED chip are electrically connected to the integrated circuit. Additionally, a coefficient of linear thermal expansion of the substrate is smaller then 20×10⁻⁶ at 20° C. The integrated circuit has a plurality of first pads, and the first LED chip and the second LED chip are electrically connected to the integrated circuit via the first pads. Besides, the LED package further comprises a plurality of first bonding wires, wherein the pads are electrically connected to the first LED chip and the second LED chip respectively via the first bonding wires. The integrated circuit has a plurality of second pads, and the carrier is electrically connected to the integrated circuit via the second pads. The light emitting device package further comprises a plurality of second bonding wires, wherein the second pads are electrically connected to the carrier via the second bonding wires.

According to an embodiment of the present invention, a wavelength of the first light is about 350 nm to about 490 nm.

According to an embodiment of the present invention, a wavelength of the second light is about 490 nm to about 700 nm.

According to an embodiment of the present invention, a wavelength of the third light is about 500 nm to about 700 nm.

According to an embodiment of the present invention, the first light is blue light, the second light is red light, and the third light is yellow light.

According to an embodiment of the present invention, the phosphor is distributed around the first LED chip.

According to an embodiment of the present invention, the encapsulant comprises a first encapsulant and a second encapsulant. The first encapsulant encapsulates the first LED chip, wherein the doped phosphor is doped in the first encapsulant. The second encapsulant encapsulates the first LED chip and the second LED chip.

According to an embodiment of the present invention, a material of the phosphors comprises yttrium-aluminum-gadolinium (YAG) series phosphor material, terbium-aluminum-gallium (TAG) series phosphor material, sulfide series phosphor material, nitride phosphor material or a combination thereof.

According to an embodiment of the present invention, the carrier is a print circuit board (PCB).

According to an embodiment of the present invention, the carrier is a leadframe.

According to the LED chip package in the present invention, two LED chips are disposed on an IC and the two LED chips, for example, emit a blue light and a red light respectively. Meanwhile, the encapsulant of the LED chip package has a doped phosphor adapted for emitting a yellow light after being excited. Therefore, a light mixing of the blue light, the yellow light and the red light is provided by the LED chip package of the present invention. The mixed light has almost all the wavelengths of the visible light thus the light emitting effect of the LED chip package is compensated. The LED chip package is apt to improving the display quality of a display.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic view of an LED chip package according to an embodiment of the present invention.

FIG. 2 is a schematic view of an LED chip package according to another embodiment of the present invention.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

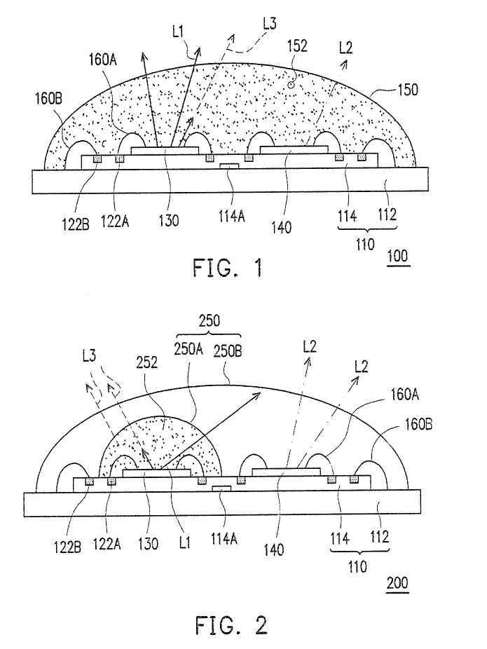

FIG. 1 is a schematic view of an LED chip package according to an embodiment of the present invention. Referring to FIG. 1, the LED chip package 100 includes a carrier 110, a first LED chip 130, a second LED chip 140 and an encapsulant 150. The carrier 110 substantially comprises a substrate 112 and an integrated circuit 114. A coefficient of linear thermal expansion of the substrate 112 is, for example, smaller then 20×10⁻⁶ at 20° C. The integrated circuit 114 is disposed on the carrier 110 and electrically connected to the carrier 110, wherein the integrated circuit 114 comprises a plurality of complementary metal-oxide-semiconductor (CMOS) devices (not shown). For example, the integrated circuit 114 is a silicon substrate having a plurality of CMOS devices. The first LED chip 130 and the second LED chip 140 are electrically connected to the carrier 110. Specifically, the first LED chip 130 is disposed on and electrically connected to the integrated circuit 114. The second LED chip 140 is disposed on and electrically connected to the integrated circuit 114. The encapsulant 150 has a doped phosphor 152, and encapsulates the integrated circuit 114, the first LED chip 130 and the second LED chip 140.

In the present embodiment, the first LED chip 130 is adapted for emitting a first light L1 and the second LED chip 140 is adapted for emitting a second light L2. At the same time, the first light L1 is adapted for exciting the doped phosphor 152 to emit a third light L3. That is to say, the first light L1 emitted from the first LED chip 130 carries with sufficient energy to excite the doped phosphor 152. The first light L1, the second light L2 and the third light L3 are substantially visible light and if the first light L1, the second light L2 and the third light L3 have different wavelengths, the mixture light of the first light L1, the second light L2 and the third light L3 may be a white light.

Substantially, a wavelength of the first light L1 is about 350 nm to about 490 nm in the present embodiment and a wavelength of the third light L3 is about 500 nm to about 700 nm. Accordingly, the first light L1 is, for example, a blue light and the third light L3 is, for example, a yellow light. The mixture light of the first light L1 and the third light L3 can be regarded as a white light. However, the wavelengths of the visible light human being can observe are about 400 nm to 700 nm. The mixture light of the first light L1 and the third light L3 may be short of the light having longer wavelength and may not present pure white in colour.

Therefore, the LED chip package 100 has the second LED chip 140 which emits a second light L2 with a wavelength about 490 nm to about 700 nm. Substantially, the second light L2 is a red light. With the disposition of the second LED chip 140, the LED chip package 100 can emit a mixture light containing most range of the wavelengths of the visible light human beings can observe and the light emitting effect of the LED chip package 100 is compensated. In other words, the second LED chip 140 is used for providing a compensating light so as to modulating the colour of the light emitted by the LED chip package 100.

In the present invention, the LED chip package 100 can provide a white light having shorter wavelength, middle wavelength and longer wavelength. Therefore, the LED chip package 100 applied to an LCD can provide an ideal light source without being arranged with other colour-LED chip packages. If the conventional design utilizes three colour-LED chip packages to provide a white light source in an LCD, the present embodiment utilizes only one LED chip package 100 to replace the three colour-LED chip packages. In a word, the amount of LED chip packages 100 used in the same LCD can be decreased to about ⅓ of the amount of the colour-LED chip packages. Accordingly, the LED chip package 100 in the present embodiment provides proper white light and is further conducive to simplifying the design of a device which needs a white light source.

In the present embodiment, the doped phosphor 152 which emits a yellow light after being excited may be yttrium-aluminum-gadolinium (YAG) series phosphor material, terbium-aluminum-gallium (TAG) series phosphor material, sulfide series phosphor material, nitride phosphor material or a combination thereof. Certainly, the doped phosphor 152 may be selected from other phosphor materials in other embodiments. Specifically, the yttrium-aluminum-gadolinium (YAG) series phosphor material may have a chemical structure like (Y₁₋ₓ, Gdₓ)₃Al₅O₁₂:Ce. Terbium-aluminum-gallium (TAG) series phosphor material may have a chemical structure like Tb₃(Al₁₋ₓ, Gaₓ)₅O₁₂:Ce or (Tb_{1-x-y}, Gdₓ, Y_{y})₃Al₅O₁₂:Ce. Sulfide series phosphor material may have a chemical structure like CaS:Ce and Ca₁₋ₓ, Srₓ)S:Eu. Nitride phosphor material may have a chemical structure like Sr—Si—O—N:Eu and Sr—Si—O—N(Cl):Eu.

The above-described wavelengths and the above-described colours of the first light L1, the second light L2 and the third light L3 are examples and the present invention is not restricted thereto. Accordingly, any type of LED chips which emits a first light L1 carries with enough energy to excite the doped phosphor to emit the third light L3 may be selected to be the first LED chip 130. Similarly, any type of LED chips which emits a second light L2 apt to compensate the shortage of the mixture light of the first light L1 and the third light L3 may be selected to be the second LED chip 140, wherein the first light L1, the second light L2 and the third light L3 are mixed into a white light.

In the LED chip package 100, the encapsulant 150 encapsulates the integrated circuit 114, the first LED chip 130 and the second LED chip 140, and the doped phosphor 152 are doped in the encapsulant 150. Herein, the doped phosphor 152 is scattered in the encapsulant 150 but the present invention is not limited thereto. Besides, the exterior of the encapsulant 150 is a lens-like structure so as to improve the light emitting effect of the LED chip package 100. In other embodiments, the exterior of the encapsulant 150 may be in the form of other shapes.

Particularly, the integrated circuit 114 has a plurality of first pads 122A and second pads 122B. The first LED chip 130 and the second LED chip 140 are electrically connected to the integrated circuit 114 via the first pads 122A and the integrated circuit 114 is electrically connected to the carrier 110 via the second pads 122B. The LED chip package 100 further comprises a plurality of first bonding wires 160A and second bonding wires 160B. The first pads 122A are electrically connected to the first LED chip 130 and the second LED chip 140 respectively via the first bonding wires 160A and the second pads 122B are substantially electrically connected to the carrier 110 via the second bonding wires 160B. Accordingly, the first LED chip 130 and the second LED chip 140 are electrically connected to the carrier 110 via the connection of the pads (122A and 122B) and the bonding wires (160A and 160B). When the LED chip package 100 is turned on, the controlling signals can be input to the first LED chip 130 and the second LED chip 140 respectively from the carrier 110.

In the present embodiment, the carrier 110 is a print circuit board (PCB), that is, the LED chip package 100 is a chip on board (COB) type LED chip package. In another embodiment, the carrier 110 can also be a leadframe, and the LED chip package 100 may be a lead frame (L/F) type LED chip package. Besides, the LED chip package 100 may further comprise a molding housing (not shown) which wraps the first LED chip 130, the second LED chip 140 and the encapsulant 150, and has a light emitting opening (not shown) for giving off the first light L1, the second light L2 and the third light L3.

FIG. 2 is the LED chip package according to another embodiment of the present invention. Referring to FIG. 2, LED chip package 200 is similar to the LED chip package 100 and the same element disposed in the two is marked in the same number. The difference between the LED chip package 200 and the LED chip package 100 is the design of the encapsulant 250. The encapsulant 250 comprises a first encapsulant 250A and a second encapsulant 250B. The first encapsulant 250A encapsulates the first LED chip 130, wherein the doped phosphor 252 is doped in the first encapsulant 250A. The second encapsulant 250B encapsulates the first encapsulant 250A, the second LED chip 140 and the integrated circuit 114.

In the LED chip package 200, the first encapsulant 250A encapsulates the first LED chip 130 and the doped phosphor 252 is only doped in the first encapsulant 250A. Accordingly, the doped phosphor 252 is distributed around the first LED chip 130 thus the doped phosphor 252 can be excited efficiently by the first light L1 emitted by the first LED chip 130. That is to say, the light emitting efficiency of the doped phosphor 252 is further improved and the LED chip package 200 can have a higher light emitting quality. In the present embodiment, the doped phosphor 252 is distributed in the first encapsulant 250A to obtain a higher light emitting effect. In another embodiment, the doped phosphor 252 may also be concentrated and distributed just above the first LED chip 130 and the present invention is not limited thereto.

Further, the LED chip package 200 can emit a white light has longer wavelength, middle wavelength and shorter wavelength among the wavelengths of the visible light. Therefore, the LED chip package 200 used in a colourful LCD can provide proper white light for the colourful LCD to present good image quality.

The LED chip package provided in the present invention comprises two LED chips, and the two LED chips are suitable for emitting the first light having shorter wavelength and the second light having longer wavelength respective. The first light carries with sufficient energy to excite the doped phosphor in the encapsulant to emit a third light having middle wavelength. Thus, the LED chip package emits a white light mixing of the first light, the second light and the third light. The LED chip package used in a colour LCD is apt to improving the display quality. In addition, one LED chip package of the present invention can provide a proper white light without being arranged with other colour-LED chip packages so that the device volume using the LED chip package of the present invention can be refined.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. A light emitting diode (LED) chip package, comprising:
a carrier;
a first LED chip disposed on and electrically connected to the carrier, wherein the first LED chip emits a first light;
a second LED chip disposed on and electrically connected to the carrier, wherein the second LED chip emits a second light;
an encapsulant having a doped phosphor, and directly contacting and directly encapsulating the first LED chip and the second LED chip, wherein the first light excites the doped phosphor to emit a third light, and the first light is blue light, the second light is red light, and the third light is yellow light.

2. The light emitting device package according to claim 1, wherein the carrier comprises a substrate and an integrated circuit, the integrated circuit is disposed on the substrate and electrically connected to the substrate, the integrated circuit comprises a plurality of complementary metal-oxide-semiconductor (CMOS) devices, and the first LED ship and the second LED chip are electrically connected to the integrated circuit.

3. The light emitting device package according to claim 2, wherein a coefficient of linear thermal expansion of the substrate is smaller than 20×10⁻³ at 20° C.

4. The light emitting device package according to claim 2, wherein the integrated circuit has a plurality of first pads, the first LED chip and the second LED chip are electrically connected to the integrated circuit via the first pads.

5. The light emitting device package according to claim 4, further comprising a plurality of first bonding wires, wherein the first pads are electrically connected to the first LED chip and the second LED chip respectively via the first bonding wires.

6. The light emitting device package according to claim 2, wherein the integrated circuit has a plurality of second pads, the substrate is electrically connected to the integrated circuit via the second pads.

7. The light emitting device package according to claim 6, further comprising a plurality of second bonding wires, wherein the second pads are electrically connected to the substrate via the second bonding wires.

8. The light emitting device package according to claim 1, wherein a wavelength of the first light is 350 nm to about 490 nm.

9. The light emitting device package according to claim 1, wherein a wavelength of the second light is 490 nm to about 700 nm.

10. The light emitting device package according to claim 1, wherein a wavelength of the third light is 500 nm to about 700 nm.

11. (canceled)

12. The light emitting device package according to claim 1, wherein the phosphor is distributed around the first LED chip.

13. (canceled)

14. The light emitting device package according to claim 1, wherein a material of the phosphors comprises yttrium-aluminum-gadolinium (YAG) series phosphor material, terbium-aluminum-gallium (TAG) series phosphor material, sulfide series phosphor material, nitride phosphor material or a combination thereof.

15. The light emitting device package according to claim 1, wherein the carrier is a print circuit board (PCB).

16. The light emitting device package according to claim 1, wherein the carrier is a leadframe.
